(19) United States
(12) Patent Application Publication
(10) Pub. No.: US 2012/0208349 A1
(43) Pub. Date: Aug. 16, 2012

(54) Support for Wafer Singulation

(75) Inventors: John O'Halloran, Swords (IE); John Tully, Virginia (IE); Billy Diggin, Delgany (IE); Richard F. Toftness, Loveland, CO (US)

(73) Assignee: Electro Scientific Industries, Inc., Portland, OR (US)

(21) Appl. No.: 12/223,046

(22) PCT Filed: Feb. 1, 2007
(86) PCT No.: PCT/EP2007/000873

§ 371 Date: Apr. 5, 2011

(30) Foreign Application Priority Data
Feb. 2, 2006 (GB) 0602114.1

(51) Int. Cl. H01L 21/78; B23B 31/30; H01L 21/683

(52) U.S. Cl. 438/463; 269/296; 279/3; 257/E21.599

(57) ABSTRACT

A support substrate or chuck 20 supports wafer die 11 during and after dicing of a wafer 10. The support substrate comprises an array of islands 21, upper faces of which are raised above a major face of the support substrate for alignment with an array of dies on, or singulated from, the wafer. Spacing between the islands is not less than a kerf of a laser, or a width of a blade, used to dice the wafer. For laser dicing the upper faces of the islands are a sufficient height above the major face that energy of a laser beam 30 used to dice the wafer is dissipated in channels between the islands without substantially machining the support substrate.

### CROSS-REFERENCE TO RELATED APPLICATIONS

This application claims priority from UK Patent GB 0602114.1 filed Feb. 2, 2006 and is the national phase of PCT application PCT/EP2007/000873 filed Feb. 1, 2007.

### FIELD OF THE INVENTION

This invention relates to a support for a substrate during division of the substrate into die, in particular for a semiconductor wafer substrate during singulation of the wafer substrate into individual integrated circuit die, particularly using a laser.

### BACKGROUND OF THE INVENTION

In a known wafer singulation process for separating a semiconductor wafer into individual die using a wafer saw, the wafer is first mounted on a dicing tape (normally a PVC or polyolephin material to which the wafer is affixed by a layer of adhesive) supported by a dicing frame and added to a stack of similarly mounted wafers. A mounted wafer is then taken from the stack of similarly mounted wafers by a handling system within a dicing saw apparatus and transferred to a flat chuck for support during dicing. Following automatic vision or operator-based alignment of wafer streets between die of the wafer with a dicing saw blade, the blade passes from one side of the wafer to an opposed side of the wafer along the wafer streets in both the x and y directions, cutting through the wafer but not through the tape. This results in an array of individual die affixed by adhesive to a mounting tape supported by a tape frame.

This tape frame with singulated die is passed to a die picker and following thermal or UV release of the adhesive, a die pin is used to push the die from the tape to allow an individual die to be picked up by the die picker.

Recently, lasers have been used instead of mechanical wafer saws for singulating wafers in this way, a laser dicing process being compatible with some types of tapes, for example, polyolephin tapes.

This known process has several drawbacks. The use of tape and tape frames adds cost to the process of singulation. Thin wafers (that is wafers less than 100 micron thick) are extremely fragile and the handling processes from wafer mounting to die release place significant stresses and strain on the wafer and on individual die.

It is an object of the present invention at least to ameliorate the aforesaid disadvantages in the prior art. In particular, it is an objective of this invention to avoid a requirement for tape during the dicing process, particularly for laser-based dicing.

### SUMMARY OF THE INVENTION

According to a first aspect of the invention there is provided a support substrate for supporting die of a wafer during and after dicing of the wafer, the support substrate comprising an array of islands, upper faces of which are raised above a major face of the support substrate for alignment with an array of dies on, or singulated from, the wafer, wherein spacing between the islands is not less than a kerf of a laser, or a width of a blade, used to dice the wafer and wherein the upper faces of the islands are a sufficient height above the major face that energy of a laser beam used to dice the wafer is dissipated in channels between the islands without substantially machining the support substrate

Conveniently, the height of the upper faces of the islands above the major face is greater than a depth of focus of the laser beam.

Advantageously, the support substrate is a vacuum chuck such that the die are retainable on the support substrate by a partial vacuum.

Conveniently, the die are retainable on the support substrate by the partial vacuum after dicing, for subsequent processing.

Alternatively, the support substrate is hollow for supporting a semiconductor wafer with an active face of the wafer towards the support substrate.

According to a second aspect of the invention, there is provided a method of dicing a wafer comprising the steps of: providing a laser beam; providing a support substrate comprising an array of islands with upper faces of the islands raised above a major face of the support substrate for alignment with an array of die on the wafer; mounting the wafer on the support substrate with the array of die aligned with the array of islands; and supporting the die on the respective islands while singulating the die from the wafer with the laser beam such that, after passing through the wafer, energy of the laser beam is dissipated in channels between the islands without substantially machining the support substrate.

Advantageously, the step of providing a support substrate comprises providing a vacuum chuck and the step of mounting the wafer on the support substrate comprises retaining the wafer on the support substrate by a partial vacuum.

Conveniently, the singulated die are retained on the support substrate by the partial vacuum for further processing after singulation.

Advantageously, the singulated die are retained on the support substrate for at least one of washing, wet etching, dry etching, Xenon difluoride etching, die testing and die picking.

Alternatively, the support substrate is hollow; the wafer is mounted on the support substrate with an active face towards the support substrate and the wafer is diced from a backside, opposed to the active side.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the accompanying drawings, in which:

FIG. 1 is a top view of a wafer suitable for use in the invention;

FIG. 2 is a top view of a support substrate or chuck according to the invention;

FIG. 3 is a vertical cross-section along the line 3-3 in FIG. 2; and

FIG. 4 is a side view of the support substrate or chuck of FIG. 2.

### DETAILED DESCRIPTION OF PREFERRED EMBODIMENTS

Throughout the description, identical reference numerals are used to identify like parts.

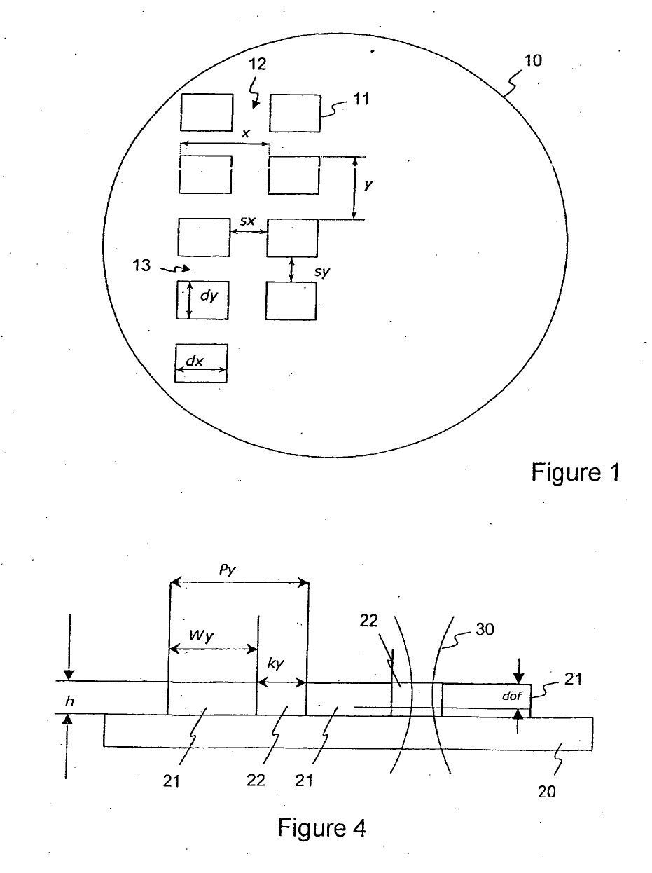

Referring to FIG. 1, a wafer 10 of diameter D has a regular array of rectangular die 11 formed thereon, the die having dimensions dx by dy and pitches of x and y as shown in FIG. 1 and the first column of Table 1. The die are spaced apart by streets 12 in a y direction of width sx and by streets 13 in an x direction of width sy. For clarity all the die 11 on the wafer 10 are shown of equal size, however the invention is not limited to such equally sized die, to rectangular shaped die, or to a regular array.

TABLE 1
definition of wafer and chuck parameters.

| Wafer level parameters | Chuck parameters |
|---|---|
| Die pitch in x direction = x | Island width in x direction = Wx |
| Die pitch in y direction = y | Island width in x direction = Wy |
| Die dimension in x direction = dx | Island pitch in x direction = Px |
| Die dimension in y direction = dy | Island pitch in y direction = Py |
| Street width in x direction = sx | Island kerf in x direction = Px − Wx |
| Street width in y direction = sy | Island kerf in y direction = Py − Wy |
| Wafer diameter = D | Chuck diameter = C |
| Wafer thickness = t | Island height = h |

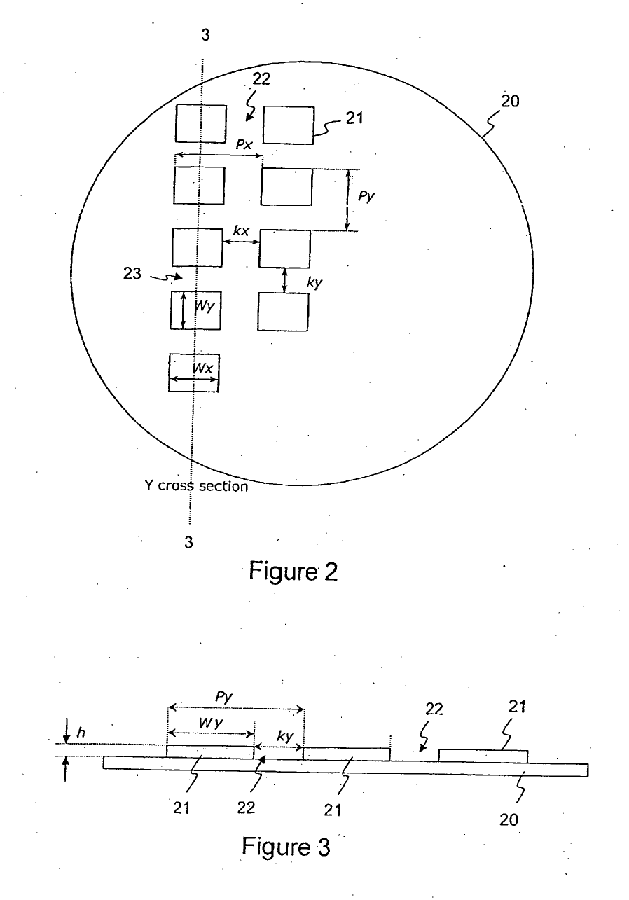

Referring to FIGS. 2 to 4, a top view of a chuck 20, according to the invention, for supporting the wafer 10, is illustrated in FIG. 2. A vertical cross-section in the y direction along the line 3-3 in FIG. 2 is shown in FIG. 3. The chuck 20 is a circular disc of similar diameter C to the diameter D of the wafer 10, in which a upper major face is provided with an array of raised rectangular islands 21 corresponding to, and arranged for alignment with, the array of die 11 on the wafer 10. Thus islands 21 have dimensions Wx by Wy and pitches of Px and Py, respectively, as shown in FIG. 2 and the second column of Table 1. The islands 21 are spaced apart by channels 22 in a y direction, of width kx, and by channels 23 in an x direction, of width ky.

The purpose of the islands 21 is to support individual die 11 during and after dicing. Referring to FIG. 4, use of the chuck 20 during laser dicing allows a laser beam 30 to pass between die 11 and dissipate energy in the channel 22, 23 between chuck islands 21 during the dicing process.

The following factors are relevant in the design of the chuck 20.

### Island Size

In order to support the die 11 but allow the laser beam 30 to pass between the islands 21, the island dimensions Wx, Wy must, in general, be at most as large as die dimensions dx, dy, respectively.

However, in some cases laser machining offers the possibility of reduced kerf. In these instances where a width of the wafer street 12, 13 has not been reduced to take advantage of this reduced kerf, the island size may be larger than the die size, but not more than die size plus one half of the difference between the wafer street 12, 13 and laser-formed kerf.

In general, island size should be less than die size. Wx<dx and Wy<dy

### Island Kerf

Following the requirement for island size Wx, Wy, it is preferable that the island kerf kx, ky, i.e. the separation between nearest edges of two islands in a particular axis, is at least as large as the respective wafer street sx, sy. In any case, the island spacing must be at least as large as the laser kerf or saw blade width. This is to ensure, in laser dicing, that the laser beam is always dissipated into the base of the channel 22, 23 between islands 21 during a dicing or cutting process, or, where used, a saw blade does not foul on the islands.

Island kerf should be equal to or greater than wafer street. Px−Wx=kx=kx≧sx and Py−Wy=ky≧sy

### Island Height

The depth of a channel 22, 23 or trench between islands 21, i.e. the height of the islands, should be greater than a “depth of machining” i.e. the depth of focus for which the intensity of the laser beam 30 at a distance d from a plane of the beam focus or waist, is reduced below an intensity for machining material from which the chuck 20 is made. This is illustrated in FIG. 4. The depth of focus, dof, is preferably smaller than the height h of the island 21.

In addition to the above requirements, the chuck 20 is preferably constructed to allow a vacuum hold even when removed from a dicing machine. Furthermore, the chuck 20 is preferably designed such that when one or more die 11 are removed from the chuck 20, airflow is sufficient that a partial vacuum remains on all other die 11 still mounted on the chuck 20 sufficient to retain the remaining die on the chuck until removed by, for example, a die picker.

In one embodiment the chuck 20 facilitates subsequent processes, such as allowing the diced wafer 10 to be lifted after the dicing process for subsequent processes, for example lifting into a wash station. Following washing an individual die 11 can be picked directly from the chuck 20 without need of a tape. Typical processes after dicing include washing, etching (wet etch, dry etch, Xenon difluoride etch), die testing and die picking.

In a further embodiment, a wafer 10 may be mounted facing downward on the chuck and diced from a backside of the wafer. For example, by placing the wafer 10 facing downward on a hollow chuck, alignment, using camera-based imaging systems to locate known features, is possible from the downward-facing, patterned side of the wafer. Following alignment, the support chuck can be placed on an active side of the wafer whilst maintaining registration between the wafer and a cutting system. Thus, in short, the camera can see the pattern if a hollow chuck is used initially, the system works by then placing the “island” chuck on the “aligned” wafer front side. In this embodiment, dicing is possible from the backside of the wafer.

The basic principle of the support substrate 20, or chuck, is that it provides each die 11 with a support “island” 21 which holds the individual die 11 in place during and after a singulation process and further allows picking of individual die 11 from the chuck 20 when placed in a “die pick” machine. The chuck design includes a channel 22, 23 between the islands 21 which allows energy of a laser beam 30, used to singulate the die, to dissipate into the support chuck 20 as the laser beam machines between the die. The channel depth h is sufficient to allow the laser beam 30 to expand so that the beam intensity is reduced to a level at which it does not machine the chuck material.

An advantage of the invention is an elimination of dicing tape and dicing frames from the dicing process. As well as reducing costs and reducing possible die damage or stress due to die picking, this results in reduced inter die abrasion. Considering a 75 micron thick wafer, following laser singulation, the laser-formed kerf is typically close to 25 microns in width. This creates a 3:1 aspect ratio (depth to width). Movement of the wafer on tape can result in die touching each other and potentially result in some level of chipping on the dice wafer. This problem is overcome by the invention.

Alternative embodiments of the invention can be implemented as a computer program product for use with a computer system, the computer program product being, for example, a series of computer instructions stored on a tangible data recording medium, such as a diskette, CD-ROM, ROM, or fixed disk, or embodied in a computer data signal, the signal being transmitted over a tangible medium or a wireless medium, for example microwave or infrared. The series of computer instructions can constitute all or part of the functionality described above, and can also be stored in any memory device, volatile or non-volatile, such as semiconductor, magnetic, optical or other memory device.

Although the present invention has been described with reference to preferred embodiments, workers skilled in the art will recognize that changes may be made in form and detail without departing from the spirit and scope of the invention.

We claim:

1. A support substrate for supporting die of a wafer during and after dicing of the wafer with a laser beam, the support substrate comprising an array of islands, upper faces of which are raised above a major face of the support substrate for alignment with an array of dies on, or singulated from, the wafer, wherein spacing between the islands is not less than a kerf of a laser, used to dice the wafer and wherein the upper faces of the islands are a sufficient height above the major face that energy of a laser beam used to dice the wafer is dissipated in channels between the islands without substantially machining the support substrate.

2. A support substrate as claimed in claim 1, wherein the height of the upper faces of the islands above the major face is greater than a depth of focus of the laser beam.

3. A support substrate as claimed in claim 1, wherein the support substrate is a vacuum chuck such that the die are retainable on the support substrate by a partial vacuum.

4. A support substrate as claimed in claim 1, wherein the die are retainable on the support substrate by the partial vacuum after dicing, for subsequent processing.

5. A support substrate as claimed in claim 1, wherein the support substrate is hollow for supporting a semiconductor wafer with an active face of the wafer towards the support substrate.

6. A method of dicing a wafer comprising the steps of:
a. providing a laser beam;
b. providing a support substrate comprising an array of islands with upper faces of the islands raised above a major face of the support substrate for alignment with an array of die on the wafer;
c. mounting the wafer on the support substrate with the array of die aligned with the array of islands; and
d. supporting the die on the respective islands while singulating the die from the wafer with the laser beam such that, after passing through the wafer, energy of the laser beam is dissipated in channels between the islands without substantially machining the support substrate.

7. A method as claimed in claim 6, wherein the step of providing a support substrate comprises providing a vacuum chuck and the step of mounting the wafer on the support substrate comprises retaining the wafer on the support substrate by a partial vacuum.

8. A method as claimed in claim 7, wherein the singulated die are retained on the support substrate by the partial vacuum for further processing after singulation.

9. A method as claimed in claim 8, wherein the singulated die are retained on the support substrate for at least one of washing, wet etching, dry etching, Xenon difluoride etching, die testing and die picking.

10. A method as claimed in claim 6, wherein the support substrate is hollow; the wafer is mounted on the support substrate with an active face towards the support substrate and the wafer is diced from a backside, opposed to the active side.
